(19) United States
(12) Patent Application Publication
(10) Pub. No.: US 2026/0082543 A1
(43) Pub. Date: Mar. 19, 2026

(54) SEMICONDUCTOR DEVICE AND METHOD OF MANUFACTURING SEMICONDUCTOR DEVICE

(71) Applicant: Kioxia Corporation, Tokyo (JP)

(72) Inventors: Ryuji KAMIYA, Yokkaichi Mie (JP); Hikaru MITOMORI, Nagoya Aichi (JP); Kei SAKAMOTO, Yokohama Kanagawa (JP); Shoichi KABUYANAGI, Yokkaichi Mie (JP); Yuki WAKISAKA, Yokkaichi Mie (JP); Kiichi SATO, Yokkaichi Mie (JP); Kotaro NODA, Yokkaichi Mie (JP); Shosuke FUJII, Kuwana Mie (JP)

(21) Appl. No.: 19/069,138

(22) Filed: Mar. 3, 2025

(30) Foreign Application Priority Data
Sep. 13, 2024 (JP) 2024-159433

(51) Int. Cl. H10B 12/00

(52) U.S. Cl. CPC H10B 12/315; H10B 12/05

(57) ABSTRACT

A semiconductor device includes a first electrode, a first insulating layer on the electrode, a gate electrode on the first layer, a second insulating layer on the gate electrode, a second electrode on the second layer, a channel layer extending in a first direction between the first and second electrodes and penetrating the first layer, the gate electrode, and the second layer, one end of the channel layer connected to the first electrode, and the other end of the channel layer connected to the second electrode, and a gate insulating layer between the channel layer and the gate electrode. In the first insulating layer, a width of the channel layer in a second direction intersecting the first direction varies discontinuously in the first direction and the width of the channel layer surrounded by the gate electrode is less than the width of the channel layer contacting the first electrode.

### CROSS-REFERENCE TO RELATED APPLICATION

This application is based upon and claims the benefit of priority from Japanese Patent Application No. 2024-159433, filed Sep. 13, 2024, the entire contents of which are incorporated herein by reference.

### FIELD

Embodiments described herein relate generally to a semiconductor device and a method of manufacturing the semiconductor device.

### BACKGROUND

Semiconductor devices that include vertical transistors in which composite oxide semiconductors are channel layers are known. Such semiconductor devices include channel layers that are connected to upper and lower electrodes at both ends and are connected to gate electrodes provided between the electrodes on the side surface.

The channel layers penetrate through the gate electrodes and interlayer insulating layers separating the upper and lower electrodes. When diameters of the lower ends of the channel layers connected to the lower electrodes vary, contact resistance between the channel layers and the lower electrodes may increase in some cases.

### BRIEF DESCRIPTION OF THE DRAWINGS

FIGS. 1A to 1C are schematic views illustrating a structure of a semiconductor device according to a first embodiment.

FIGS. 2Aa to 2Bf are sectional views illustrating parts of a method of manufacturing the semiconductor device according to the first embodiment.

FIGS. 3Aa to 3Bd are sectional views illustrating parts of the method of manufacturing the semiconductor device according to the first embodiment.

FIGS. 4Aa to 4Bd are sectional views illustrating parts of the method of manufacturing the semiconductor device according to the first embodiment.

FIGS. 5A and 5B are schematic views illustrating a structure of a semiconductor device according to a second embodiment.

FIGS. 6Aa to 6Bd are sectional views illustrating parts of a method of manufacturing the semiconductor device according to the second embodiment.

FIGS. 7Aa to 7Bd are sectional views illustrating parts of the method of manufacturing the semiconductor device according to the second embodiment.

FIGS. 8Aa to 8Bd are sectional views illustrating parts of a method of manufacturing the semiconductor device according to Modified Example 1 of the second embodiment.

FIGS. 9A and 9B are schematic views illustrating a structure of a semiconductor device according to Modified Example 2 of the second embodiment.

FIGS. 10Aa to 10Bd are sectional views illustrating parts of a method of manufacturing the semiconductor device according to Modified Example 2 of the second embodiment. and

FIG. 11 is a schematic view illustrating definition of a taper angle when it is considered that channel layers have a tapered shape according to the second embodiment and Modified Examples 1 and 2.

### DETAILED DESCRIPTION

Embodiments provide a semiconductor device capable of reducing contact resistance between a channel layer and a lower electrode and a method of manufacturing the semiconductor device.

In general, according to one embodiment, a semiconductor device comprises a first electrode, a first insulating layer on the first electrode, a gate electrode on the first insulating layer, a second insulating layer on the gate electrode, a second electrode on the second insulating layer, a channel layer extending in a first direction between the first and second electrodes and penetrating the first insulating layer, the gate electrode, and the second insulating layer, one end of the channel layer being connected to the first electrode, and the other end of the channel layer being connected to the second electrode, and a gate insulating layer between the channel layer and the gate electrode. In the first insulating layer, a width of the channel layer in a second direction intersecting the first direction varies discontinuously in the first direction and the width of the channel layer surrounded by the gate electrode is less than the width of the channel layer contacting the first electrode.

Hereinafter, embodiments of the present disclosure will be described in detail with reference to the drawings. The following embodiments do not limit the present disclosure. Elements in the following embodiments include elements easily assumed by those skilled in the art and substantially the same elements.

### First Embodiment

Hereinafter, a first embodiment will be described in detail with reference to the drawings.

### Structure of Semiconductor Device

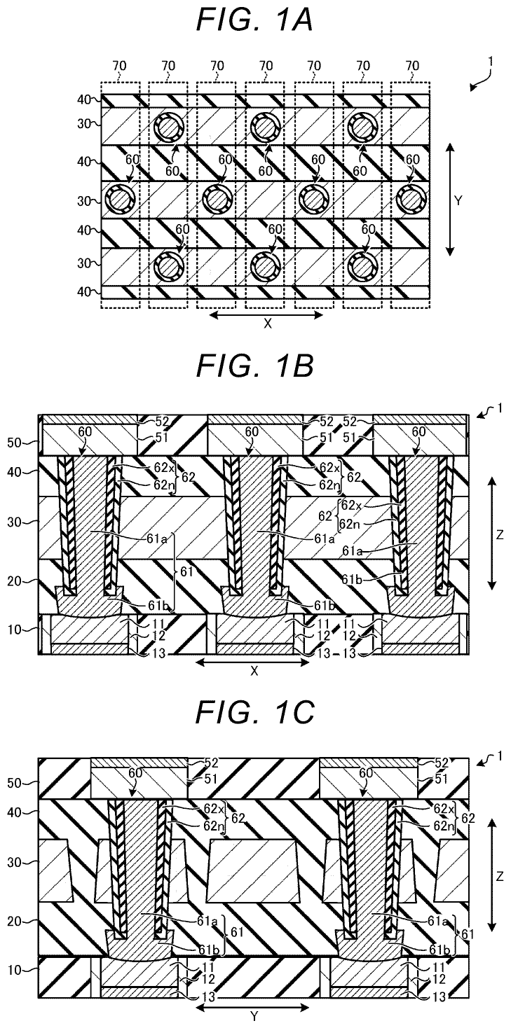

FIGS. 1A to 1C are schematic views illustrating a structure of a semiconductor device 1 according to the first embodiment. FIG. 1A is an XY sectional view of the semiconductor device 1 at a height location of a gate electrode 30 to be described below. FIG. 1B is a sectional view of the semiconductor device 1 in the X direction. FIG. 1C is a sectional view of the semiconductor device 1 in the Y direction.

In the present specification, both the X and Y directions are directions oriented along a surface of the gate electrode 30 to be described below. The X and Y directions are orthogonal to each other. The Z direction is a stacking direction of layers in the semiconductor device 1 and is a direction orthogonal to the X and Y directions.

An extension direction of the gate electrode 30 is referred to as a first direction. The first direction is a direction oriented in the X direction. A direction that is an extension direction of a bit line 70 to be described below and intersects the first direction is referred to as a second direction. The second direction is a direction oriented in the Y direction. Here, due to a manufacturing error in the semiconductor device 1, the first and second directions are not necessarily orthogonal to each other.

As illustrated in FIGS. 1A to 1C, the semiconductor device 1 includes a lower electrode 11, a gate electrode 30, an upper electrode 51, and a pillar 60. The lower electrode 11, the gate electrode 30, the upper electrode 51, and the pillar 60 are provided above a substrate (not illustrated) such as a silicon substrate.

More specifically, insulating layers 10 and 20, the gate electrode 30, and insulating layers 40 and 50 are provided in this order above the substrate. A layer thickness of the gate electrode 30 and the insulating layers 20 and 40 is, for example, about several tens of nanometers.

The insulating layer 10 is, for example, a SiN layer. In the insulating layer 10, contacts 13 extending in the insulating layer 10 are provided at at a predetermined interval in the X and Y directions. The contact 13 is, for example, a SiGe layer and is connected to the substrate directly or via a source line (not illustrated).

At an upper end of the contact 13, the lower electrode 11 that is, for example, an indium tin oxide (ITO) layer is provided. Accordingly, the lower electrode 11 is at a substrate potential. Upper surfaces of the insulating layer 10 and the lower electrode 11 are located on substantially the same plane, and the upper surface of the lower electrode 11 is not covered with the insulating layer 10.

Side surfaces of the contact 13 and the lower electrode 11 are covered with a liner layer 12. The liner layer 12 orients to the outside from the side of the contact 13 and the lower electrode 11 and has a multilayer structure in which, for example, a TiN layer, a ZrO layer, and a ZrAlO layer (none of which is illustrated) are stacked in this order.

The insulating layer 20 covering the upper surfaces of the insulating layer 10, the contact 13, and the lower electrode 11 are provided on the insulating layer 10. The insulating layer 20 serving as a first insulating layer is, for example, a SiO layer. The insulating layer 20 may be a low-k layer such as a SiOC layer.

The plurality of gate electrodes 30 that extend in a direction oriented in the X direction and are arrayed at a predetermined interval in the Y direction are provided on the insulating layer 20. The plurality of gate electrodes 30 are tungsten layers or the like and are provided at locations overlapping in the Z direction with the lower electrodes 11 arrayed in a grid form in the X and Y directions. The above-described insulating layer 20 is also provided between the gate electrodes 30 adjacent in the Y direction.

Here, spaces between the gate electrodes 30 adjacent in the Y direction may be filled with an insulating layer 40 that is an upper layer of the gate electrodes 30. Such differences arise due to, for example, a variation in a timing at which patterning of the gate electrodes 30 is performed by, for example, a method of manufacturing the semiconductor device 1, which will be described below.

The insulating layer 40 covering the gate electrodes 30 is provided on the plurality of gate electrodes 30. The insulating layer 40 may be formed of the same material as the insulating layer 20 and is, for example, a SiO layer or a low-k layer such as SiOC layer.

The insulating layer 50 such as a SiO layer is provided on the insulating layer 40. On the lower surface side of the insulating layer 50, the plurality of upper electrodes 51 are provided at locations overlapping in the Z direction with the plurality of lower electrodes 11. The upper electrodes 51 are, for example, ITO layers like the lower electrodes 11 and are connected to the bit lines 70 located higher than the insulating layer 50 via plugs 52 penetrating through the insulating layer 50. The plurality of bit lines 70 each extend in a direction oriented in the Y direction and are arrayed at a predetermined interval in the X direction.

At locations interposed between the lower electrode 11 and the upper electrodes 51, the insulating layer 40, the gate electrodes 30 corresponding to the locations, and the plurality of pillars 60 penetrating through the insulating layer 20 are provided. Each of the plurality of pillars 60 includes a channel layer 61 and a gate insulating layer 62.

The channel layer 61 includes a lower channel layer 61b and an upper channel layer 61a and penetrates through the insulating layer 40, the gate electrode 30, and the insulating layer 20 to be connected to the lower electrode 11 and the upper electrode 51. The channel layer 61 is a composite oxide semiconductor layer such as an IGZO layer that is an oxide layer of indium (In), gallium (Ga), and zinc (Zn).

The lower channel layer 61b is provided in the insulating layer 20 and is connected to the lower electrode 11 at a lower end. The upper end of the lower channel layer 61b is disposed at a height location between both surfaces of the insulating layer 20 in the Z direction. The height location of the upper end of the lower channel layer 61b is also referred to as a first height location.

The upper channel layer 61a is connected to the upper electrode 51 at an upper end, penetrates through the insulating layer 40 and the gate electrode 30, further extends in the insulating layer 20, and is connected to the upper end of the lower channel layer 61b at a lower end. At this time, the lower end of the upper channel layer 61a may extend in the lower channel layer 61b at the lower end.

Both the lower channel layer 61b and the upper channel layer 61a have a circular shape when viewed, for example, in the Z direction, and the diameter of the lower channel layer 61b is larger than the diameter of the upper channel layer 61a. Here, the lower channel layer 61b and the upper channel layer 61a may have any shape other than the circular shape such as an elliptical shape or an oval shape. Even in this case, a cross-sectional area of the lower channel layer 61b is greater than a cross-sectional area of the upper channel layer 61a when viewed in the Z direction.

That is, both lengths of the lower channel layer 61b in the X and Y directions are greater than lengths of the upper channel layer 61a in the X and Y directions.

At this time, the upper channel layer 61a may have a shape in which a diameter, that is, lengths in the X and Y directions, at the lower end is less than a diameter, that is, lengths in the X and Y directions, at the upper end. That is, the upper channel layer 61a may have a tapered shape that has a diameter decreasing from the upper end to the lower end.

Here, the upper channel layer 61a may have a sidewall that is substantially vertical so that the diameter at the lower end is substantially the same as the diameter at the upper end.

The lower channel layer 61b may have a shape in which a diameter, that is, lengths in the X and Y directions, at the lower end is less than a diameter, that is, lengths in the X and Y directions, at the upper end. That is, the lower channel layer 61b may have a tapered shape that has a diameter decreasing from the upper surface side to the lower surface side of the insulating layer 20. Even in this case, the diameter of the lower channel layer 61b is mostly greater than the diameter of the upper channel layer 61a.

The lower channel layer 61b may have a sidewall that is substantially vertical so that the diameter at the lower end is substantially the same as the diameter at the upper end.

Both the lower channel layer 61b and the upper channel layer 61a are composite oxide semiconductor layers such as IGZO layers, as described above. The composite oxide semiconductor layers in the lower channel layer 61b and the upper channel layer 61a may have the same composition ratio of various metals in the composite oxide semiconductor layers or may have different composition ratios.

For example, when the composite oxide semiconductor layers are IGZO layers and have the same composition ratio of various metals, the lower channel layer 61b and the upper channel layer 61a may have a composition ratio of In:Ga:Zn=1:1:1.

When the composition ratios of various metals are set to be different, it is preferable that a concentration of a metal (metal atoms) with a lower oxygen binding strength than the other metals (metal atoms), among the metals in the composite oxide semiconductor layer, is higher in the lower channel layer 61b than in the upper channel layer 61a. Conversely, it is preferable that a concentration of a metal with higher oxygen binding strength than the other metals is higher in the upper channel layer 61a than in the lower channel layer 61b.

For example, when the composite oxide semiconductor layer is an IGZO layer, In among In, Ga, and Zn contained in the IGZO layer has characteristics of a lower oxygen binding strength than the other metals. Accordingly, when the composition ratios of various metals are set to be different, the lower channel layer 61b may have a composition ratio of In:Ga:Zn=2:1:1.

On the other hand, Ga has characteristics that an oxygen binding strength is higher than the other metals. Accordingly, when the composition ratios of various metals are set to be different, the upper channel layer 61a may have a composition ratio of In:Ga:Zn=1:2:1 instead of or in addition to the lower channel layer 61b with the above-described composition ratio.

As described above, the semiconductor device 1 is formed with, for example, vertical transistors. That is, the vertical transistor can be turned on by applying a predetermined voltage from the gate electrode 30 to the channel layer 61 of the pillar 60 penetrating through the gate electrode 30.

Accordingly, it may be supposed that one pillar 60, and the lower electrode 11, the gate electrode 30, and the upper electrode 51 that are connected to each pillar 60 are formed as one vertical transistor, and the semiconductor device 1 includes a plurality of vertical transistors. In the vertical transistor, the gate electrode 30 applying a voltage to the channel layer 61 functions as a word line.

As described above, in the IGZO layer, In has a lower oxygen binding strength than the other metals. Therefore, oxygen is more likely to dissociates from In—O bonds, which generates holes serving as doners in a track along the oxygen dissociates. In the lower channel layer 61b directly connected to the lower electrode 11, as described above, by increasing a concentration of a metal such as In that has a lower oxygen binding strength than the other metals and easily generates doners, it is possible to increase the number of doners in the composite semiconductor layer, raise an ON current of the semiconductor device 1 formed with the vertical transistors, and operate the semiconductor device 1 at a high speed.

As described above, Ga in the IGZO layer has a higher oxygen binding strength than the other metals. Therefore, oxygen is less likely to dissociate from a Ga—O bond, which makes it difficult to generate holes serving as doners. In the upper channel layer 61a directly affected by an electric field effect from the gate electrode 30, as described above, by increasing a concentration of a metal such as Ga that has a higher oxygen binding strength than the other metals and rarely generates doners, it is possible to decrease the number of doners in the composite semiconductor layer, raise a threshold voltage of the semiconductor device 1 formed with the vertical transistors, and reduce a leakage current.

Accordingly, by further increasing a concentration of a metal such as Ga in the upper channel layer 61a while increasing a concentration of a metal such as In in the lower channel layer 61b, it is also possible to make a high-on-current and a high threshold voltage compatible in the vertical transistor.

The gate insulating layer 62 extends in the insulating layer 40, the gate electrode 30, and the insulating layer 20 like the above-described upper channel layer 61a and covers a sidewall portion of the upper channel layer 61a. As described above, when the lower end of the upper channel layer 61a extends in the lower channel layer 61b, the lower end of the gate insulating layer 62 may also extend in the lower channel layer 61b.

The gate insulating layer 62 has, for example, a multilayer structure in which a gate insulating layer 62x and a gate insulating layer 62n are stacked in this order from the channel layer 61 side. The gate insulating layer 62x is, for example, a SiO layer and the gate insulating layer 62n is, for example, a SiN layer. The gate insulating layer 62n covering the gate insulating layer 62x from the outside may also cover the lower end of the gate insulating layer 62x.

### Method of Manufacturing Semiconductor Device

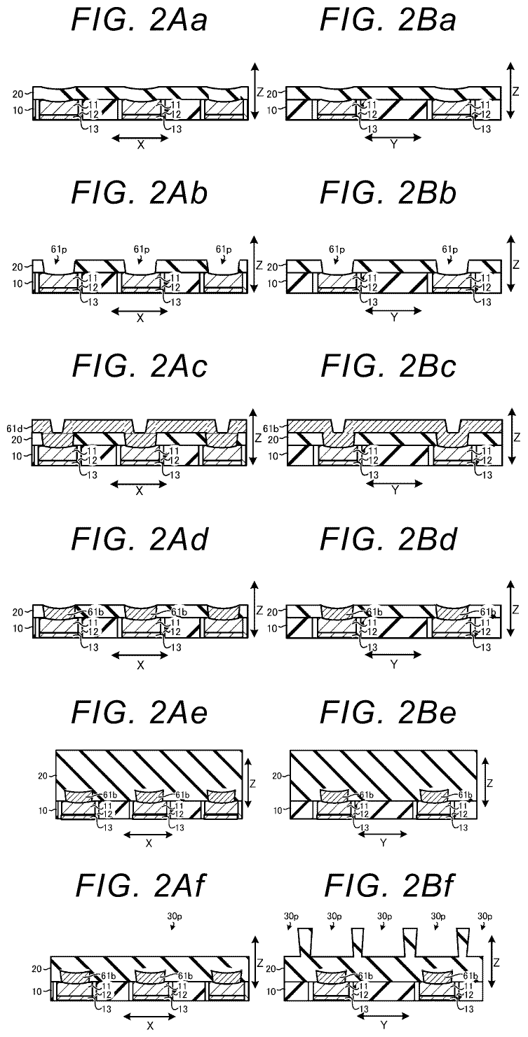

Next, a method of manufacturing the semiconductor device 1 according to the first embodiment will be described with reference to FIGS. 2Aa to 4Bd.

FIGS. 2Aa to 4Bd are sectional views illustrating parts of the method of manufacturing the semiconductor device 1 according to the first embodiment. More specifically, drawings to which A is attached among FIGS. 2Aa to 4Bd are sectional views of the semiconductor device 1 in the X direction during manufacturing and drawings to which B is attached among FIGS. 2Aa to 4Bd are sectional views of the semiconductor device 1 in the Y direction during manufacturing.

As illustrated in FIGS. 2Aa and 2Ba, the insulating layer 10 such as a SiN layer is formed above the substrate. The plurality of contacts 13 penetrating through the insulating layer 10 are formed and the plurality of lower electrodes 11 are formed at the upper ends of the contacts 13. The liner layer 12 covering sidewalls of the contact 13 and the lower electrode 11 is formed.

When the lower electrode 11 is formed at the upper end of the contact 13, the ITO layer that becomes the lower electrode 11 is formed to cover the entire upper surface of the insulating layer 10 including the upper end of the contact 13. Thereafter, the ITO layer is processed into the shape of the lower electrode 11 by chemical mechanical polishing (CMP) or the like so that the upper surface of the ITO layer is located on substantially the same plane as the upper surface of the insulating layer 10. At this time, the upper surface of the lower electrode 11 has a depression called dishing.

The insulating layer 20 such as a SiO layer or a low-k layer covering the upper surfaces of the insulating layer 10 and the lower electrode 11 is formed. At this time, the insulating layer 20 is formed thinner than a final layer thickness of the insulating layer 20 of the semiconductor device 1 and is formed, for example, by a layer thickness of the above-described lower channel layer 61b.

As illustrated in FIGS. 2Ab and 2Bb, a plurality of recess patterns 61p are formed at locations at which channel layers 61 are to be formed later in the insulating layer 20. At this time, the recess pattern 61p has a tapered shape in which a diameter decreases from the upper surface side to the lower surface side of the insulating layer 20.

As illustrated in FIGS. 2Ac and 2Bc, a semiconductor layer 61d such as an IGZO layer is formed to cover the entire upper surface of the insulating layer 20, including the plurality of recess patterns 61p. The plurality of recess patterns 61p are filled with the semiconductor layer 61d, and thus the upper surface of the semiconductor layer 61d may become slightly depressed at locations at which the plurality of recess patterns 61p are disposed.

As illustrated in FIGS. 2Ad and 2Bd, the semiconductor layer 61d is processed into a shape of the lower channel layer 61b by CMP or the like so that the upper surface of the semiconductor layer 61d is located on substantially the same plane as the upper surface of the insulating layer 20.

As illustrated in FIGS. 2Ae and 2Be, the insulating layer 20 is increased to cover the lower channel layers 61b. At this time, the insulating layer 20 is generated thicker than the final layer thickness of the insulating layer 20 of the semiconductor device 1 and is formed, for example, a layer thickness of the above-described gate electrode 30.

As illustrated in FIGS. 2Af and 2Bf, a plurality of groove pattern 30p extending in a direction oriented in the X direction at a predetermined interval in the Y direction are formed in the insulating layer 20. The groove patterns 30p are formed at locations overlapping in the Z direction with the plurality of lower electrodes 11.

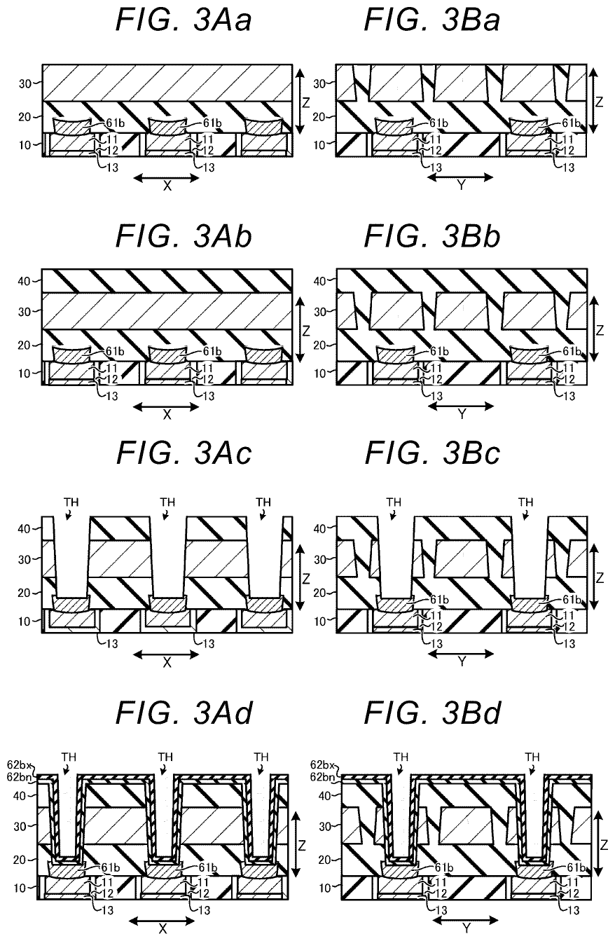

As illustrated in FIGS. 3Aa and 3Ba, a plurality of grooves 30t are filled with tungsten layers or the like. Accordingly, the plurality of gate electrodes 30 are formed in which the insulating layers 20 are formed between wirings.

As illustrated in FIGS. 3Ab and 3Bb, the insulating layer 40 such as a SiO layer or a low-k layer is formed to cover the upper surfaces of the plurality of gate electrodes 30 and the insulating layer 20.

A method of forming the gate electrodes 30 illustrated in FIGS. 2Ae and 2Be to FIGS. 3Aa and 3Ba is also referred to a damascene method. Here, the plurality of gate electrodes 30 may be formed by a method other than the damascene method.

For example, the insulating layer 20 is formed from the beginning with a final layer thickness of the insulating layer 20 of the semiconductor device 1 and a tungsten layer or the like is formed to cover the insulating layer 20. A resist layer or the like that has a pattern of the plurality of gate electrodes 30 is formed on the tungsten layer and the tungsten layer is processed by etching to form the plurality of gate electrodes 30.

After the resist layer is peeled, as illustrated in FIGS. 3Ab and 3Bb, the insulating layer 40 is formed to cover the plurality of gate electrodes 30. In this case, spaces between the plurality of gate electrodes 30 arrayed in the Y direction are filled with the insulating layer 40.

As illustrated in FIGS. 3Ac and 3Bc, at locations overlapping in the Z direction with the plurality of lower electrodes 11, a plurality of through via holes TH that penetrate through the insulating layer 40 and the gate electrodes 30, further extend in the insulating layer 20, and reach the lower channel layers 61b are formed. At this time, the lower ends of the through via holes TH may extend slightly in the lower channel layers 61b.

As illustrated in FIGS. 3Ad and 3Bd, a gate insulating layer 62bx such as a SiO layer and a gate insulating layer 62bn such as a SiN layer are formed in this order to cover a side wall and a bottom surface of each of the plurality of through via holes TH. At this time, the gate insulating layers 62bx and 62bn also cover the upper surface of the insulating layer 40.

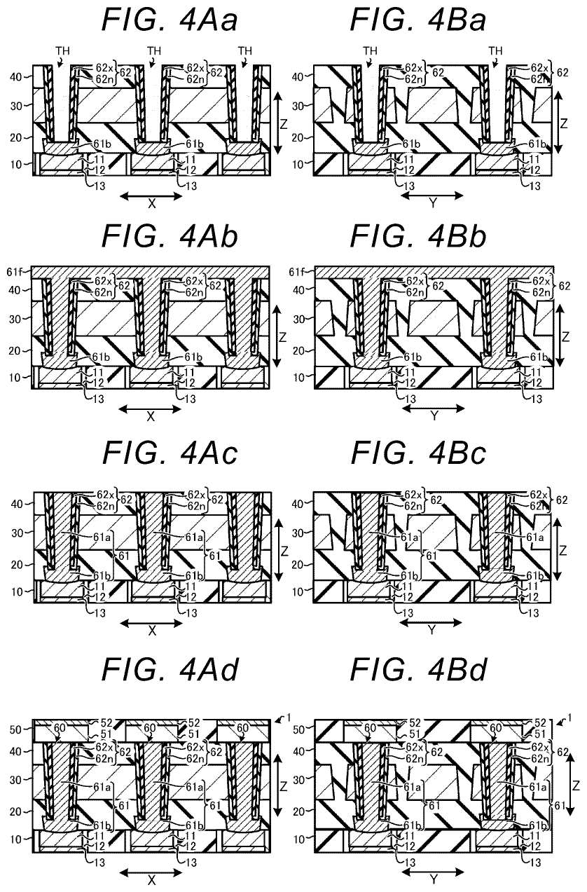

As illustrated in FIGS. 4Aa and 4Ba, the gate insulating layers 62bx and 62bn are removed from the bottom surface of each of the plurality of through via holes TH. At this time, the gate insulating layer 62bx may remain at the lower end of the gate insulating layer 62bn remaining on the sidewall of the through via hole TH. At this time, the gate insulating layers 62bx and 62bn of the upper surface of the insulating layer 40 are removed.

Accordingly, the gate insulating layer 62 is formed to cover the sidewall of the individual through via hole TH. The upper end of the lower channel layer 61b is exposed on the bottom surface of the through via hole TH.

As illustrated in FIGS. 4Ab and 4Bb, for example, a semiconductor layer 61f such as an IGZO layer is formed in the plurality of through via holes TH using, for example, an atomic layer deposition (ALD) method. At this time, the semiconductor layer 61f also covers the upper surface of the insulating layer 40.

As illustrated in FIGS. 4Ac and 4Bc, the semiconductor layer 61f on the upper surface of the insulating layer 40 is removed by a CMP or the like. Accordingly, the semiconductor layer 61f is individually separated to form the plurality of upper channel layers 61a respectively connected to the plurality of lower channel layers 61b. Accordingly, the channel layers 61 each including the lower channel layer 61b and the upper channel layer 61a are formed, and the plurality of pillars 60 each including the channel layer 61 and the gate insulating layer 62 are formed.

As illustrated in FIGS. 4Ad and 4Bd, the insulating layer 50 such as a SiO layer is formed to cover the upper surfaces of the plurality of pillars 60 and the insulating layer 40. The plurality of upper electrodes 51 are formed in the insulating layer 50, and the plurality of plugs 52 that penetrate through the insulating layer 50 and are connected to the upper electrodes 51 are formed.

In this way, the semiconductor device 1 according to the first embodiment is manufactured.

### SUMMARY

Miniaturization is achieved in the semiconductor device formed with the vertical transistors. Accordingly, a pillar diameter including the channel layer is also reduced. The pillar is formed to penetrate through an interlayer insulating layer that separates the upper and lower electrodes from each other and the gate electrode provided between the upper and lower electrodes. However, the reduction in the pillar diameter may result in a variation in the diameter of the lower end of the through via hole and an increase in contact resistance between the lower electrode and the channel layer of the pillar in some cases.

The gate insulating layer covering the sidewall of the channel layer has, for example, a multilayer structure of a SiO layer and a SiN layer in some cases. When the gate insulating layer is formed, the SiN layer and the SiO layer are formed in this order on the sidewall and the bottom surface of the above-described through via hole. However, when the SiN layer is formed on the lower electrode layer such as an ITO layer, the ITO layer may sublimate by a reducing action of a material gas or the like of the SiN layer and the lower electrode may be lost in some cases.

In the semiconductor device 1 according to the first embodiment, at a predetermined height location between both ends of the insulating layer 20 in the layer thickness direction, a length of the channel layer 61 in the X direction increases discontinuously toward the lower electrode 11 from the gate electrode 30 side. Accordingly, it is possible to reduce the contact resistance between the channel layer 61 and the lower electrode 11.

In the semiconductor device 1 according to the first embodiment, in the composite oxide semiconductor layer in the lower channel layer 61b, a concentration of a metal with a lower oxygen binding strength than the other metals among a plurality of metals is higher than that of the composite oxide semiconductor layer in the upper channel layer 61a. Accordingly, it is possible to increase an ON current of the semiconductor device 1 and operate the semiconductor device 1 at a high speed.

In the semiconductor device 1 according to the first embodiment, in the composite oxide semiconductor layer in the upper channel layer 61a, a concentration of a metal with a higher oxygen binding strength than the other metals among a plurality of metals is higher than that of the composite oxide semiconductor layer in the lower channel layer 61b. Accordingly, it is possible to increase a threshold voltage of the semiconductor device 1 and reduce a leakage current.

In the method of manufacturing the semiconductor device 1 according to the first embodiment, the forming of the channel layer 61 includes: forming the lower channel layer 61b with a predetermined length in the X direction in the insulating layer 20 on the lower electrode 11; and forming the upper channel layer 61a that extends from the insulating layer 40 to the insulating layer 10, is connected to the lower channel layer 61b in the insulating layer 10, and has a length less than the length of the lower channel layer 61b in the X direction.

Accordingly, it is possible to reduce the contact resistance between the channel layer 61 and the lower electrode 11. The lower channel layer 61b and the upper channel layer 61a are formed in two steps. Therefore, it is possible to improve embeddability of the composite oxide semiconductor layer in the channel layer 61 and further reduce the contact resistance between the channel layer 61 and the lower electrode 11.

The through via hole TH serving as the upper channel layer 61a reaches the upper surface of the lower channel layer 61b without reaching the lower electrode 11. Therefore, it is possible to cause the lower channel layer 61b to function as a stopper layer and curb damage to the lower electrode 11 when the through via hole TH is formed.

In the method of manufacturing the semiconductor device 1 according to the first embodiment, the forming of the gate insulating layer 62 includes forming the gate insulating layer 62bn on the sidewall and the bottom surface of the through via hole TH that extends from the insulating layer 40 to the insulating layer 20 and is connected to the lower channel layer 61b in the insulating layer 20.

In this way, when the gate insulating layer 62 is formed, the gate insulating layer 62bn that is a SiN layer or the like is formed on the lower channel layer 61b without being formed directly on the lower electrode 11. Accordingly, the ITO layer or the like forming the lower electrode 11 is inhibited from sublimating by a reducing action of a material gas of the gate insulating layer 62bn and the lower electrode 11 is inhibited from being lost.

### Second Embodiment

Hereinafter, a second embodiment will be described in detail with reference to the drawings. In the second embodiment, the shape of the channel layer 161 and a method of forming the channel layer 161 are different from those of the above-described first embodiment.

In the following drawings, similar reference signs are given to similar elements to the above-described first embodiment and description thereof will be omitted in some cases.

### Structure of Semiconductor Device

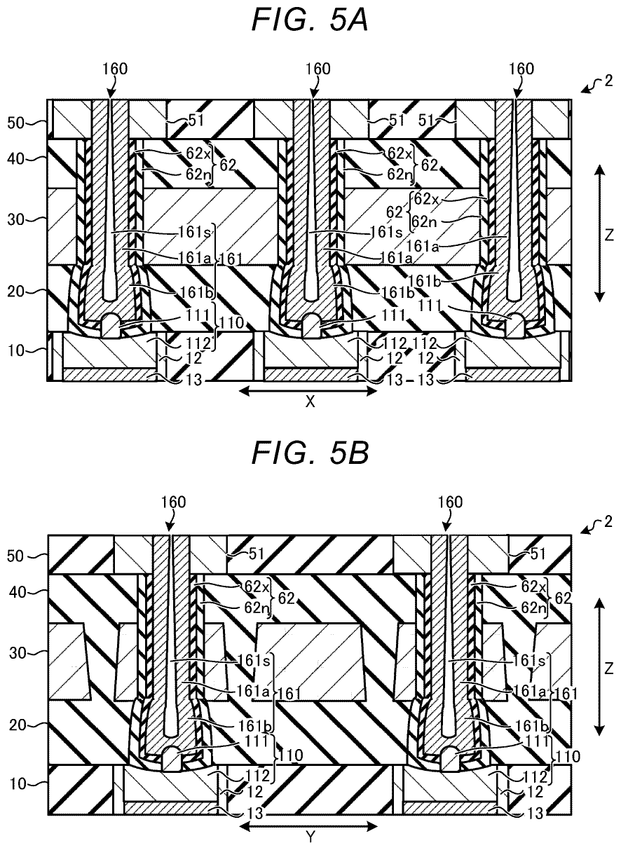

FIGS. 5A and 5B are schematic views illustrating a structure of a semiconductor device 2 according to the second embodiment. FIG. 5A is a sectional view of the semiconductor device 2 in the X direction. FIG. 5B is a sectional view of the semiconductor device 2 in the Y direction.

As illustrated in FIGS. 5A and 5B, instead of the lower electrode 11 according to the above-described first embodiment, a lower electrode 110 of the semiconductor device 2 includes a base electrode 112 and a protrusion electrode 111.

The base electrode 112 is, for example, a TiN layer and is provided at the upper end of the contact 13 so that a height location of the upper surface is substantially the same as the upper surface of the insulating layer 10. The protrusion electrode 111 is, for example, an ITO layer and protrudes upward from the upper surface of the base electrode 112.

A pillar 160 of the semiconductor device 2 includes a channel layer 161 instead of the channel layer 61 according to the above-described first embodiment.

The channel layer 161 is a composite oxide semiconductor layer such as an IGZO layer, includes an upper channel layer 161a and a lower channel layer 161b, penetrates through the upper electrode 51, the insulating layer 40, the gate electrode 30, and the insulating layer 20, and is accordingly connected to the lower electrode 110 and the upper electrode 51. The channel layer 161 may include a gap 161s extending in the Z direction across the upper channel layer 161a and the lower channel layer 161b.

The upper channel layer 161a and the lower channel layer 161b may both have, for example, a circular shape when viewed in the Z direction or may have different shapes such as an elliptical shape or an oval shape.

The upper channel layer 161a penetrates through the upper electrode 51, the insulating layer 40, and the gate electrode 30 and reach the upper surface of the insulating layer 20. The upper channel layer 161a has a sidewall that is substantially vertical. Accordingly, a diameter, that is, lengths in the X and Y directions, at the lower end of the upper channel layer 161a is substantially equal to a diameter, that is, lengths in the X and Y directions, at the upper end.

Here, the upper channel layer 161a may have a tapered shape that has a diameter decreasing from the upper surface side to the lower surface side of the insulating layer 20.

The lower channel layer 161b is connected to the lower end of the upper channel layer 161a at the upper end, penetrates through the insulating layer 20, and is connected to the protrusion electrode 111 protruding from the upper surface of the base electrode 112 at the lower end. In other words, the protrusion electrode 111 penetrates through the gate insulating layer 62 at the lower end of the lower channel layer 161b and protrudes to the lower channel layer 161b. Accordingly, the lower channel layer 161b is connected to the lower electrode 110.

The lower channel layer 161b has a shape in which a diameter, that is, lengths in the X and Y directions, at the lower end is greater than a diameter, that is, lengths in the X and Y directions, at the upper end. At this time, the diameter of the lower channel layer 161b continuously changes throughout from the upper end to the lower end.

That is, the lower channel layer 161b has a tapered shape in which a diameter increases from the upper surface side to the lower surface side of the insulating layer 20. Here, the lower channel layer 161b may have a bowing shape in which a sidewall portion is slightly swollen toward the outside.

Accordingly, the lower channel layer 161b has a diameter that is substantially the same as the diameter of the lower end of the upper channel layer 161a at the upper end. The lower channel layer 161b has a diameter greater than a maximum diameter of the upper channel layer 161a at the lower end. That is, the lower channel layer 161b has a length greater than a maximum length of the upper channel layer 161a in the X and Y directions at the lower end.

As described above, the channel layer 161 according to the second embodiment has a tapered shape in which a diameter mostly increases from the upper end to the lower end.

The gate insulating layer 62 of the semiconductor device 2 covers the sidewall of the channel layer 161 and the bottom surface of the channel layer 161 except for the penetration portion of the protrusion electrode 111 at the height locations of the insulating layer 40, the gate electrode 30, and the insulating layer 20. The gate insulating layer 62 does not cover the sidewall of the channel layer 161 at a portion penetrating through the upper electrode 51. Accordingly, the channel layer 161 can come into contact with the upper electrode 51 on the sidewall.

### Method of Manufacturing Semiconductor Device

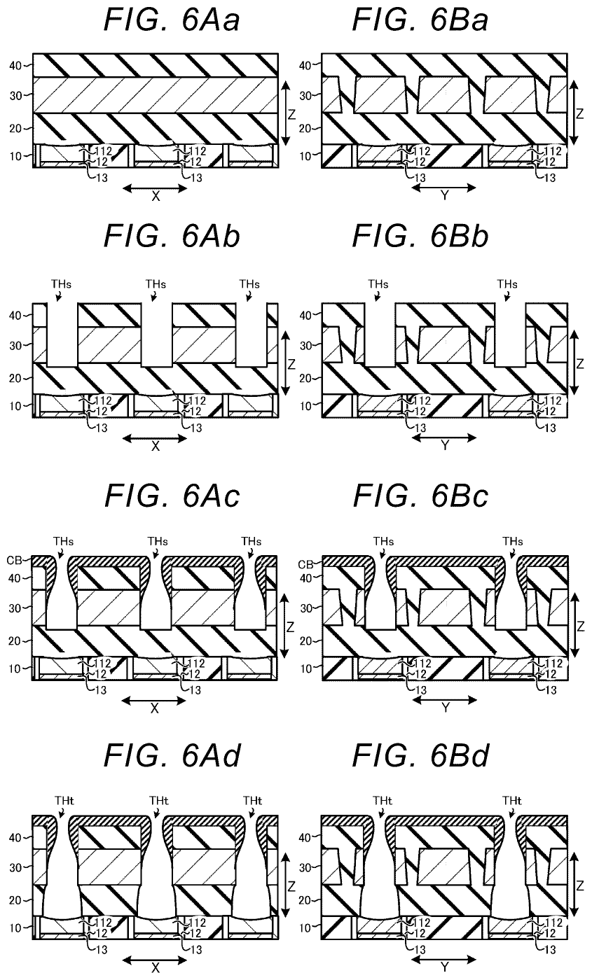

Next, a method of manufacturing the semiconductor device 2 according to the second embodiment will be described with reference to FIGS. 6Aa to 7Bd.

FIGS. 6Aa to 7Bd are sectional views illustrating parts of a method of manufacturing the semiconductor device 2 according to the second embodiment. More specifically, drawings to which A is attached among FIGS. 6Aa to 7Bd are sectional views of the semiconductor device 2 in the X direction during manufacturing and drawings to which B is attached among FIGS. 6Aa to 7Bd are sectional views of the semiconductor device 2 in the Y direction during manufacturing.

As illustrated in FIGS. 6Aa and 6Ba, the insulating layer 10 such as a SiN layer is formed above the substrate, and the plurality of contacts 13, the plurality of base electrodes 112, and the liner layers 12 are formed in the insulating layer 10. The insulating layer 20 such as a SiO layer or a low-k layer, the gate electrode 30, and the insulating layer 40 such as a SiO layer or a low-K layer are formed in this order on the insulating layer 10.

That is, except for the process of forming the lower channel layer 61b in the insulating layer 20, the above processes are performed, for example, similarly to the processes until FIGS. 3Aa and 3Ba according to the above-described first embodiment.

As illustrated in FIGS. 6Ab and 6Bb, at locations overlapping in the Z direction with the plurality of base electrodes 112, a plurality of through via holes THs that penetrate through the insulating layer 40 and the gate electrode 30 and reach the upper surface of the insulating layer 20 are formed.

The plurality of through via holes THs can be formed using, for example, reactive ion etching or the like under a condition that anisotropy is high. Accordingly, the through via holes THs of which sidewalls are substantially vertical are formed.

As illustrated in FIGS. 6Ac and 6Bc, sidewall protection layers CB are formed on the sidewalls of the plurality of through via holes THs.

The sidewall protection layer CB can be obtained by forming, for example, a chemical vapor deposition (CVD)-carbon layer to cover the upper surface of the insulating layer 40 in which the plurality of through via holes THs are formed under the condition that a coverage property is deteriorated. Alternatively, by using a condition that it is easy to generate deposition with a CF-based etching gas in the processes of FIGS. 6Ab and 6Bb described above, it is possible to form a CF-based deposition as the sidewall protection layer CB on the sidewall of the through via hole THs concurrently with the forming of the through via hole THs.

As illustrated in FIGS. 6Ad and 6Bd, when additional etching is further performed on the bottom surface of the through via hole THs with the sidewall of the through via hole THs protected by the sidewall protection layer CB, a through via hole THt penetrating through the insulating layer 40, the gate electrode 30, and the insulating layer 20 is formed.

At this time, by performing additional etching of the through via hole THs under the condition that anisotropy is weakened and side etching is facilitated, it is possible to expand the diameter of the bottom surface of the through via hole THt. Accordingly, it is possible to obtain the through via hole THt that has a substantially vertical shape at a height location of the insulating layer 40 and the gate electrode 30 and has a larger diameter than the upper vertical portion at the height location of the lower surface of the insulating layer 20.

Thereafter, the sidewall protection layer CB is removed by an ashing process using, for example, an oxygen plasma or the like.

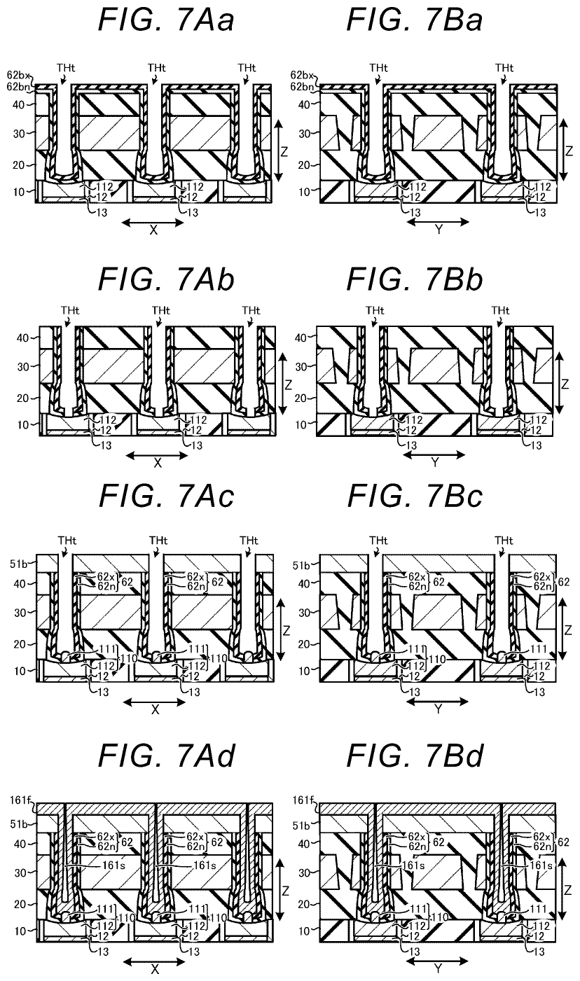

As illustrated in FIGS. 7Aa and 7Ba, the gate insulating layer 62bx such as a SiO layer and the gate insulating layer 62bn such as a SiN layer are formed in this order to cover the sidewall and the bottom surface of each of the plurality of through via holes THt. At this time, the gate insulating layers 62bx and 62bn also cover the upper surface of the insulating layer 40.

The base electrode 112 that is a TiN layer or the like is exposed on the bottom surface of the through via hole THt. In this way, since the gate insulating layer 62bn such as a SiN layer is formed without being coming into direct contact with the protrusion electrode 111 such as an ITO layer formed later, the protrusion electrode 11 can also be inhibited from being lost by the method according to the second embodiment.

As illustrated in FIGS. 7Ab and 7Bb, the gate insulating layers 62bx and 62bn are removed from the bottom surface of each of the plurality of through via holes THt. At this time, the gate insulating layers 62bx and 62bn on the upper surface of the insulating layer 40 are also removed.

At this time, a process is performed via an opening of the upper end of the through via hole THt that has a diameter less than the diameter of the bottom surface of the through via hole THt. Accordingly, the gate insulating layers 62bx and 62bn of the bottom surface of the through via hole THt may not be completely removed. That is, the gate insulating layers 62bx and 62bn may be removed from a part of the bottom surface of the through via hole THt overlapping in the Z direction with the opening of the through via hole THt.

Accordingly, the gate insulating layer 62 covering the sidewall and parts of the bottom surface of the individual through via hole THt is formed. The upper surface of the base electrode 112 is exposed from the bottom surface of the through via hole THt from which the gate insulating layers 62bx and 62bn are removed partially.

As illustrated in FIGS. 7Ac and 7Bc, an ITO layer 51b covering the upper surface of the insulating layer 40 in which the plurality of through via holes THt are opened is formed by a physical vapor deposition (PVD) or the like. The ITO layer 51b is also formed on the bottom surface of the through via hole THt in which the base electrode 112 is exposed via the opening of the through via hole THt. Accordingly, the protrusion electrode 111 connected to the base electrode 112 at the lower end is formed to protrude the through via hole THt on the bottom surface of the through via hole THt.

As illustrated in FIGS. 7Ad and 7Bd, a semiconductor layer 161f such as an IGZO layer is formed in the plurality of through via holes THt by, for example, an ALD method. At this time, the semiconductor layer 161f also covers the upper surface of the insulating layer 40.

At this time, a process is performed via the opening of the upper end of the through via hole THt that has the diameter less than the diameter of the bottom surface of the through via hole THt. Accordingly, the through via hole THt may not be completely filled with an IGZO layer or the like. In this case, the gap 161s extending in the Z direction can arise in the semiconductor layer 161f with which the through via hole THt is filled.

Thereafter, the semiconductor layer 161f is removed from the upper surface of the insulating layer 40 by the CMP or the like. Accordingly, the individually independent channel layer 161 is formed to extend and penetrate through the ITO layer 51b, the insulating layer 40, the gate electrode 30, and the insulating layer 20. The pillar 160 including the channel layer 161 and the gate insulating layer 62 is formed.

The ITO layer 51b is processed into the pattern of the upper electrode 51 to form the plurality of upper electrodes 51 connected to the individual channel layers 161. The insulating layer 50 burying the spaces between the plurality of upper electrodes 51 is formed.

In this way, the semiconductor device 2 according to the second embodiment is manufactured.

### SUMMARY

In the semiconductor device 2 according to the second embodiment, the length of the channel layer 161 in the X direction continuously changes between both ends of the insulating layer 20 in the layer thickness direction, and the length in the X direction is greater at the height location of the lower surface of the insulating layer 20 than at the height location of the upper surface of the insulating layer 20. Accordingly, it is possible to reduce contact resistance between the channel layer 161 and the lower electrode 110.

In the semiconductor device 2 according to the second embodiment, the lower electrode 110 includes the protrusion electrode 111 that protrudes to the inside of the channel layer 161. Accordingly, it is possible to further increase a contact area of the channel layer 161 and the lower electrode 110 and further reduce the contact resistance.

In the semiconductor device 2 according to the second embodiment, it is possible to additionally obtain the same advantages as those of the semiconductor device 1 according to the above-described first embodiment.

### Modified Example 1

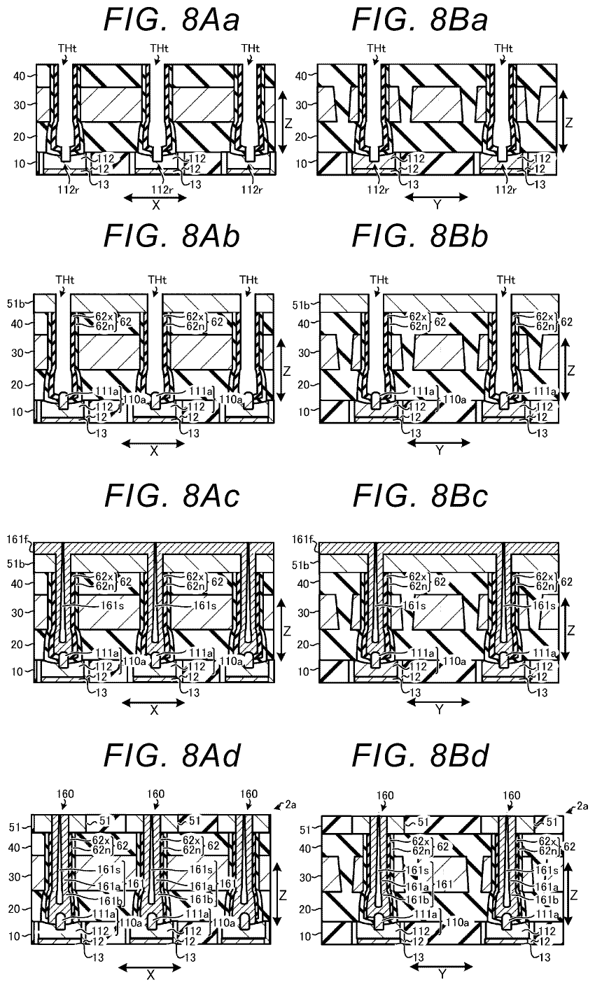

Next, a semiconductor device 2a according to Modified Example 1 of the second embodiment will be described with reference to FIGS. 8Aa to 8Bd. The semiconductor device 2a according to Modified Example 1 differs from the semiconductor device 2 according to the above-described second embodiment in that the lower end of the protrusion electrode 111a is embedded in the base electrode 112.

FIGS. 8Aa to 8Bd are sectional views illustrating parts of a method of manufacturing the semiconductor device 2a according to Modified Example 1 of the second embodiment. More specifically, FIGS. 8Aa to 8Ad are sectional views of the semiconductor device 2a in the X direction during manufacturing. FIGS. 8Ba to 8Bd are sectional views of the semiconductor device 2a in the Y direction during manufacturing.

In the following drawings, similar reference signs are given to similar elements to the above-described second embodiment and description thereof will be omitted in some cases.

In steps of manufacturing the semiconductor device 2a according to Modified Example 1, similar processes to those of FIGS. 6Aa and 6Ba to FIGS. 7Aa and 7Ba of the above-described second embodiment are performed. Accordingly, the plurality of through via holes THt penetrating through the insulating layer 40, the gate electrodes 30, and the insulating layer 20 and including the gate insulating layers 62bx and 62bn on the sidewalls and the bottom surfaces are formed.

As illustrated in FIGS. 8Aa and 8Ba, the gate insulating layers 62bx and 62bn are removed from the bottom surface of each of the plurality of through via holes THt. At this time, the gate insulating layers 62bx and 62bn on the upper surface of the insulating layer 40 are also removed.

At this time, an over-etching amount for the gate insulating layers 62bx and 62bn is increased and a part of the base electrode 112 exposed from the bottom surface of the through via hole THt after the removing of the gate insulating layers 62bx and 62bn is also removed. Accordingly, a recess portion 112r is formed at the upper end of the base electrode 112.

As illustrated in FIGS. 8Ab and 8Bb, the ITO layer 51b is formed to cover the upper surface of the insulating layer 40 by a PVD method or the like. The ITO layer 51b is also formed on the bottom surface of the through via hole THt in which the base electrode 112 is exposed.

Accordingly, the recess portion 112r of the base electrode 112 is filled with the ITO layer 51b, and the protrusion electrode 111a having the lower end extending in the base electrode 112 and an upper end protruding in the through via hole THt is formed. A lower electrode 110a including the protrusion electrode 111a and the base electrode 112 is formed.

Subsequent processes are performed similarly to those of the above-described second embodiment.

That is, as illustrated in FIGS. 8Ac and 8Bc, the through via hole THt is filled with the semiconductor layer 161f such as an IGZO layer. As illustrated in FIGS. 8Ad and 8Bd, the semiconductor layer 161f is individually detached to form the pillar 160 including the channel layer 161 and the gate insulating layer 62. The ITO layer 51b is patterned to form the upper electrode 51.

In this way, the semiconductor device 2a according to Modified Example 1 is manufactured.

In the semiconductor device 2a according to Modified Example 1, the lower end of the protrusion electrode 111a extends in the base electrode 112. Accordingly, it is possible to further increase a contact area of the protrusion electrode 111a and the base electrode 112 and further reduce the contact resistance.

In the semiconductor device 2a according to Modified Example 1, it is possible to additionally obtain the same advantages as those of the semiconductor device 2 according to the above-described second embodiment.

### Modified Example 2

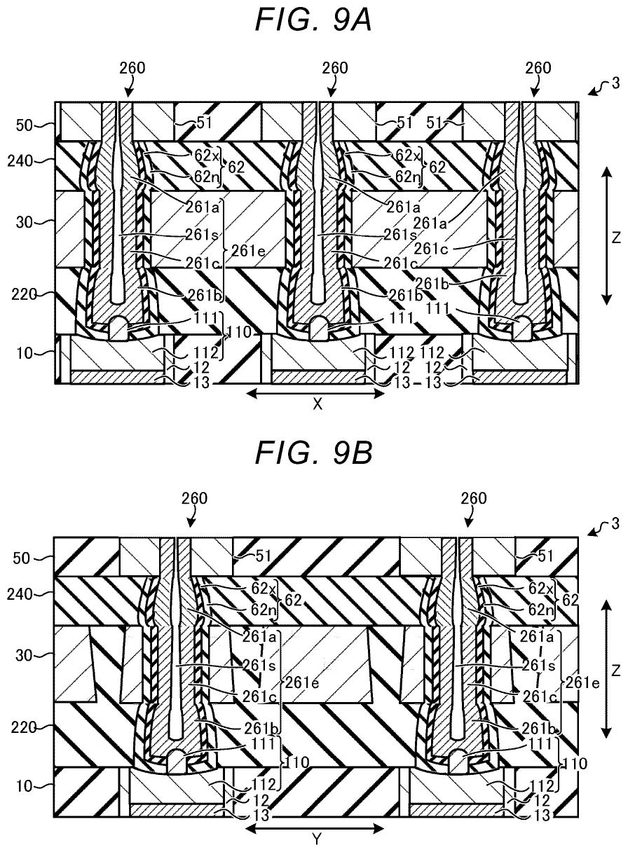

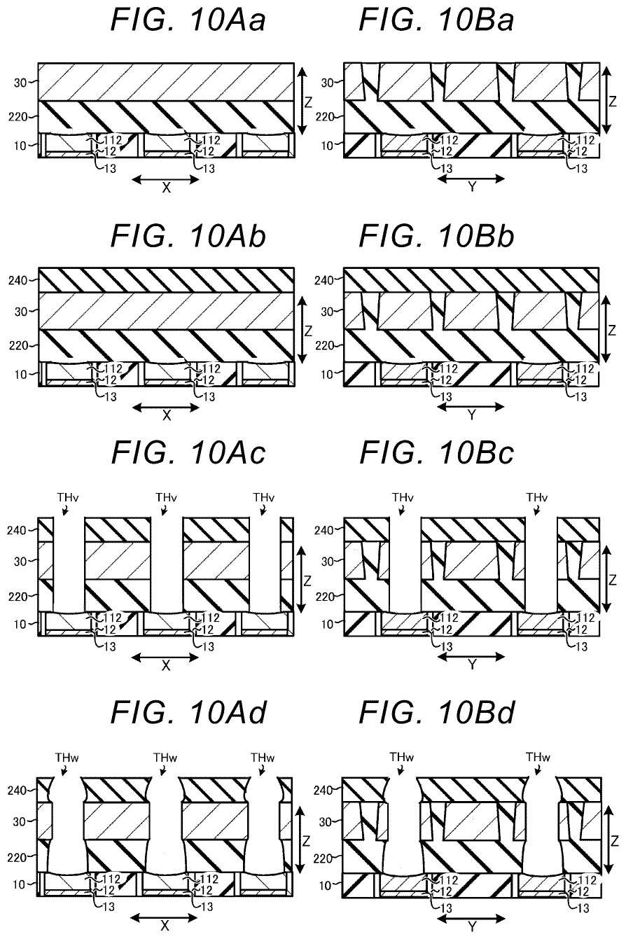

Next, a semiconductor device 3 according to Modified Example 2 of the second embodiment will be described with reference to FIGS. 9A to 10Bd. The semiconductor device 3 according to the Modified Example 2 differs from that of the above-described second embodiment in the shape of a channel layer 261.

In the following drawings, similar reference signs are given to similar elements to the above-described first embodiment and description thereof will be omitted in some cases.

FIGS. 9A and 9B are schematic views illustrating a structure of the semiconductor device 3 according to Modified Example 2 of the second embodiment. FIG. 9A is a sectional view of the semiconductor device 3 in the X direction. FIG. 9B is a sectional view of the semiconductor device 3 in the Y direction.

As illustrated in FIGS. 9A and 9B, the semiconductor device 3 includes insulating layers 220 and 240 instead of the insulating layers 20 and 40 according to the above-described second embodiment. Both the insulating layers 220 and 240 may be SiO layers or low-k layers as in the above-described second embodiment. Here, the insulating layer 220 has density lower than the insulating layer 240.

A pillar 260 of the semiconductor device 3 includes a channel layer 261e instead of the channel layer 161 according to the above-described second embodiment.

The channel layer 261e is a composite oxide semiconductor layer such as an IGZO layer, includes an upper channel layer 261a, an intermediate channel layer 161c, and a lower channel layer 261b, penetrates through the upper electrode 51, the insulating layer 240, the gate electrode 30, and the insulating layer 220, and accordingly are connected to the lower electrode 110 and the upper electrode 51. The channel layer 261e may include a gap 261s extending in the Z direction across the lower channel layer 261b via the intermediate channel layer 261c from the upper channel layer 261a.

The upper channel layer 261a, the intermediate channel layer 261c, and the lower channel layer 261b may all have, for example, a circular shape when viewed in the Z direction or may have a different shape such as an elliptical shape or an oval shape.

The upper channel layer 261a penetrates through the upper electrode 51 and the insulating layer 240 and reaches the upper surface of the gate electrode 30.

The upper channel layer 261a has a substantially vertical sidewall in a portion penetrating through the upper electrode 51 and connected to the upper electrode 51. Accordingly, a diameter of the upper channel layer 161a, that is, lengths in the X and Y directions, at the height location of the upper surface of the upper electrode 51 is substantially the same as a diameter of the upper channel layer 161a, that is, lengths in the X and Y directions, at the height location of the lower surface of the upper electrode 51.

Here, the upper channel layer 261a may have a tapered shape that has a diameter decreasing from the upper surface side to the lower surface side of the upper electrode 51.

In the portion penetrating through the insulating layer 240, a diameter of the upper channel layer 261a, that is, lengths in the X and Y directions, at the height location of the lower surface of the insulating layer 240 is larger than a diameter of the upper channel layer 261a, that is, lengths in the X and Y directions, at the height location of the upper surface of the insulating layer 240. At this time, the diameter of the upper channel layer 261a continuously changes throughout from the height location of the upper surface of the insulating layer 240 to the height location of the lower surface.

That is, in the portion penetrating through the insulating layer 240, the upper channel layer 261a has a tapered shape in which a diameter increases from the upper surface side to the lower surface side of the insulating layer 240. Here, the upper channel layer 261a may have a bowing shape in which a sidewall portion is slightly swollen toward the outside.

The intermediate channel layer 261c is connected to the lower end of the upper channel layer 261a at the upper end, penetrates through the gate electrode 30, and reaches the upper surface of the insulating layer 220. The intermediate channel layer 261c has a sidewall that is substantially vertical. Accordingly, a diameter, that is, lengths in the X and Y directions, at the lower end of the intermediate channel layer 261c is substantially the same as a diameter, that is, lengths in the X and Y directions, at the upper end.

Here, the intermediate channel layer 261c may have a tapered shape that has a diameter decreasing from the upper surface side to the lower surface side of the gate electrode 30.

The lower channel layer 261b is connected to the lower end of the intermediate channel layer 261c at the upper end, penetrates through the insulating layer 220, and is connected to the protrusion electrode 111 protruding from the upper surface of the base electrode 112 at the lower end.

The lower channel layer 261b has a shape in which a diameter, that is, lengths in the X and Y directions, at the lower end is greater than a diameter, that is, lengths in the X and Y directions, at the upper end like the lower channel layer 161b according to the above-described second embodiment. At this time, the diameter of the lower channel layer 261b continuously changes throughout from the upper end to the lower end.

That is, the lower channel layer 261b has a tapered shape in which a diameter increases from the upper surface side to the lower surface side of the insulating layer 220. Here, the lower channel layer 261b may have a bowing shape in which a sidewall portion is slightly swollen toward the outside.

In this way, the upper channel layer 261a and the intermediate channel layer 261c correspond to the upper channel layer 161a in the channel layer 161 according to the above-described second embodiment, and the lower channel layer 262b corresponds to the lower channel layer 161b in the channel layer 161 according to the above-described second embodiment. Of these layers, the channel layer 261 according to Modified Example 2 has a different shape in the upper channel layer 261a from that of the channel layer 161 according to the above-described second embodiment.

In the above structure, a maximum diameter of the upper channel layer 261a, a maximum diameter of the intermediate channel layer 261c, and a maximum diameter of the lower channel layer 261b increase in the order of the intermediate channel layer 261c, the upper channel layer 261a, and the lower channel layer 261b (the maximum diameter of the intermediate channel layer 261c <the maximum diameter of the upper channel layer 261a<the maximum diameter of the lower channel layer 261b).

When the channel layer 261 has such a shape, the channel layer 261 according to Modified Example 2 has a shape further closer to the tapered shape in which a diameter increases from the upper end to the lower end.

FIGS. 10Aa to 10Bd are sectional views illustrating parts of a method of manufacturing the semiconductor device 3 according to Modified Example 2 of the second embodiment.

More specifically, FIGS. 10Aa to 10Ad are sectional views of the semiconductor device 3 in the X direction during manufacturing. FIGS. 10Ba to 10Bd are sectional views of the semiconductor device 3 in the Y direction during manufacturing.

As illustrated in FIGS. 10Aa and 10Ba, the insulating layer 10 including the contacts 13, the base electrodes 112, and the liner layers 12 are formed on a substrate, and the insulating layer 220 and the gate electrodes 30 are formed in this order on the insulating layer 10.

As illustrated in FIGS. 10Ab and 10Bb, the insulating layer 240 is formed on the gate electrodes 30.

Here, the insulating layers 220 and 240 are SiO layers, low-k layers, or the like and are formed by a chemical vapor deposition (CVD) method, an ALD method, or the like using a material gas of Si and an oxide gas such as an O2 gas for oxidizing Si. At this time, a film forming condition is adjusted so that density of the insulating layer 220 is lower than that of the insulating layer 240.

For example, the density of the insulating layers 220 and 240 can be adjusted by changing a flow rate of the material gas of Si to the oxide gas. More specifically, when the insulating layer 220 is formed, the density of the insulating layer 220 can be decreased by increasing the flow rate of the material gas of Si to the oxide gas. Conversely, when the insulating layer 240 is formed, the density of the insulating layer 240 can be increased by decreasing the flow rate of the material gas of Si to the oxide gas.

As illustrated in FIGS. 10Ac and 10Bc, a plurality of through via holes THv penetrating the insulating layer 240, the gate electrodes 30, and the insulating layer 220 and reaching the plurality of base electrodes 112 are formed. The plurality of through via holes THv can be formed using, for example, RIE or the like under the condition that anisotropy is high. Accordingly, the through via holes THv of which sidewalls are substantially vertical are formed.

As illustrated in FIGS. 10Ad and 10Bd, sidewall portions of the plurality of through via holes THv are processed by wet etching using a solution or the like for the insulating layers 220 and 240 that are SiO layers or low-k layers. Accordingly, through via holes THw of which sidewalls of portions penetrating through the insulating layers 220 and 240 are retreated are formed.

Here, in the above-mentioned RIE treatment, etching progresses in only the Z direction, and there is hardly any difference in the sidewall shape of the through via hole THv due to a difference in density between the insulating layers 220 and 240. However, in wet etching, the etching process progresses isotropically and an etching rate difference of, for example, about two times can be caused depending on the difference in density between the insulating layers 220 and 240.

Therefore, in the through via hole THw, a retreat speed of the sidewall by the wet etching is slow in a portion penetrating through the insulating layer 240 with high density, and a retreat speed of the sidewall by the wet etching is high in a portion penetrating through the insulating layer 220 with low density. In the through via hole THw, the sidewall of a portion penetrating through the gate electrode 30 that is a tungsten layer or the like is hardly retreated.

In this way, in the through via hole THw, a diameter of the portion penetrating through the gate electrode 30, that is, lengths in the X and Y directions, is the smallest. A diameter of the portion penetrating through the insulating layer 240, that is, lengths in the X and Y directions, is greater than that of the portion penetrating through the gate electrode 30. A diameter of the portion penetrating through the insulating layer 220, that is, lengths in the X and Y directions, is further greater than the portion penetrating through the insulating layer 240.

Subsequent processes are performed similarly to the processes after FIGS. 7Aa and 7Ba of the above-described second embodiment. Here, when the gate insulating layers 62bx and 62bn are removed from the bottom surface of the through via hole THw, the process of the above-described Modified Example 1 may be applied to form the protrusion electrode 111a of which a lower end extends in the base electrode 112.

In this way, the semiconductor device 3 according to Modified Example 2 is manufactured.

In the semiconductor device 3 according to Modified Example 2, the shape of the channel layer 261 can be further approached to a tapered shape. Accordingly, it is possible to improve embeddability of the semiconductor layer such as an IGZO layer and further reduce the contact resistance between the channel layer 261 and the lower electrode 110.

In the semiconductor device 3 according to Modified Example 2, it is possible to additionally obtain the same advantages as those of the semiconductor device 2 according to the above-described second embodiment.

In the above-described Modified Example 2, the semiconductor device 3 includes the insulating layer 220 with low density and the insulating layer 240 with high density. The density may change inside each of the insulating layers 220 and 240. That is, the insulating layers 220 and 240 may be formed so that the density gradually increases from the lower surface to the upper surface of the insulating layer 220 and the density further increases from the lower surface to the upper surface of the insulating layer 240.

In this case, when the insulating layers 220 and 240 are formed, the insulating layers 220 and 240 of which the density continuously changes in the layer can be formed by gradually decreasing the flow rate of the material gas of Si.

By processing the insulating layers 220 and 240 by wet etching, it is possible to further approach the shape of the channel layer to the tapered shape in which the diameter increases from the upper end to the lower end.

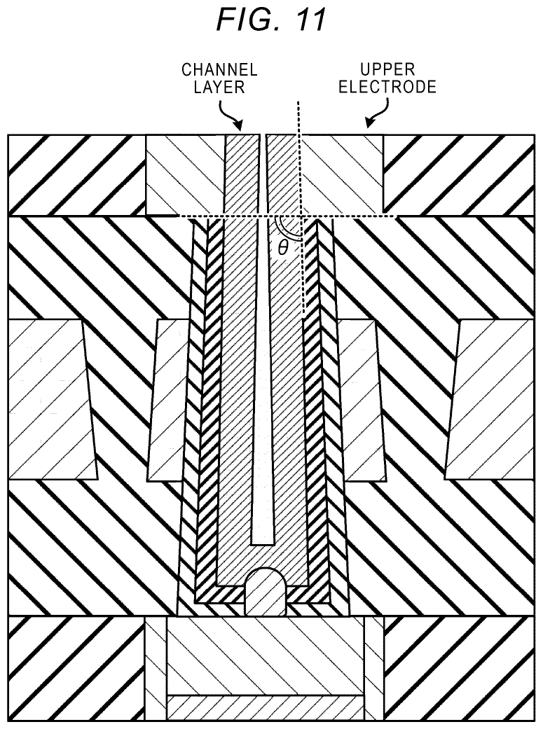

As described in the second embodiment and Modified Examples 1 and 2, the channel layers 161 and 261 are considered to have the tapered shape in which the diameter mostly increases from the upper end to the lower end. An example of definition of a taper angle of the channel layer will be described with reference to FIG. 11 schematically illustrating the channel layers 161 and 261 according to the second embodiment and Modified Examples 1 and 2.

FIG. 11 is a schematic view illustrating definition of a taper angle when it is considered that the channel layers 161 and 261 have a tapered shape according to the second embodiment and Modified Examples 1 and 2.

As illustrated in FIG. 11, when the channel layer is formed to have the tapered shape, a taper angle θ of the channel layer can be defined as an angle formed by an inner surface of the sidewall of the channel layer and the lower surface of the upper electrode. In this case, in the second embodiment and Modified Examples 1 and 2, the taper angle θ of the channel layer is greater than 90°.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor device comprising:
a first electrode;
a first insulating layer on the first electrode;
a gate electrode on the first insulating layer;
a second insulating layer on the gate electrode;
a second electrode on the second insulating layer;
a channel layer extending in a first direction between the first and second electrodes and penetrating the first insulating layer, the gate electrode, and the second insulating layer, wherein one end of the channel layer is connected to the first electrode, and the other end of the channel layer is connected to the second electrode; and
a gate insulating layer between the channel layer and the gate electrode, wherein
in the first insulating layer, a width of the channel layer in a second direction intersecting the first direction varies discontinuously in the first direction and the width of the channel layer surrounded by the gate electrode is less than the width of the channel layer contacting the first electrode.

2. The semiconductor device according to claim 1, wherein
the channel layer includes a first portion contacting the second electrode and a second portion contacting the first electrode, and
a width of the first portion in the second direction is smaller than that of the second portion.

3. The semiconductor device according to claim 2, wherein
the width of the channel layer is discontinuous at an interface between the first and second portions, the interface being located in the first insulating layer.

4. The semiconductor device according to claim 3, wherein
the width of each of the first and second portions increases continuously in an upward direction from the first electrode to the second electrode.

5. The semiconductor device according to claim 2, wherein
each of the first and second portions is a composite oxide semiconductor containing a plurality of metals.

6. The semiconductor device according to claim 5, wherein
the oxide semiconductor contains a first metal, an oxygen binding strength of which is lower than that of the other metals, and
a concentration of the first metal in the second portion is higher than a concentration of the first metal in the first portion.

7. The semiconductor device according to claim 5, wherein
the oxide semiconductor contains a second metal, an oxygen binding strength of which is higher than the other metals, and
a concentration of the second metal in the first portion is higher than a concentration of the second metal in the second portion.

8. The semiconductor device according to claim 2, wherein
the gate insulating layer surrounds a side surface of the first portion.

9. A semiconductor device comprising:
a first electrode;
a first insulating layer on the first electrode;
a gate electrode on the first insulating layer;
a second insulating layer on the gate electrode;
a second electrode on the second insulating layer;
a channel layer extending in a first direction between the first and second electrodes and penetrating the first insulating layer, the gate electrode, and the second insulating layer, wherein one end of the channel layer is connected to the first electrode, and the other end of the channel layer is connected to the second electrode; and
a gate insulating layer between the channel layer and the gate electrode, wherein in the first insulating layer, a width of the channel layer in a second direction intersecting the first direction continuously changes, and
the width of the channel layer at a first location corresponding to a lower surface of the first insulating layer is greater than the width of the channel layer at a second location corresponding to an upper surface of the first insulating layer, the upper surface being closer to the second electrode than the lower surface.

10. The semiconductor device according to claim 9, wherein
the first electrode includes a protrusion protruding into the channel layer.

11. The semiconductor device according to claim 10, wherein
the first electrode includes a base portion that supports the protrusion.

12. The semiconductor device according to claim 11, wherein
a lower end of the protrusion is in the base portion.

13. A method of manufacturing a semiconductor device, the method comprising:
forming a first electrode;
forming a first insulating layer on the first electrode;
forming a gate electrode on the first insulating layer;
forming a second insulating layer on the gate electrode; and
forming a channel layer on the first electrode and penetrating through the second insulating layer, the gate electrode, and the first insulating layer in a first direction, wherein
forming the channel layer includes:
forming, on the first electrode in the first insulating layer, a second portion that has a first width in a second direction interesting the first direction, and
forming, on the second portion in the first insulating layer, the gate electrode, and the second insulating layer, a first portion that has a second width in the second direction, the second width being less than the first width.

14. The method according to claim 13, wherein
forming the first portion includes:
forming a through via hole that extends from the second insulating layer to the first insulating layer and reaches the second portion in the first insulating layer,
forming a gate insulating layer on a sidewall of the through via hole, and
filling the through via hole with a first composite oxide semiconductor containing a plurality of metals.

15. The method according to claim 14, wherein
forming the gate insulating layer includes:
forming a first gate insulating layer on the sidewall and a bottom surface of the through via hole,
forming a second gate insulating layer on the sidewall and the bottom surface of the through via hole with the first gate insulating layer interposed therebetween, and
removing the first and second gate insulating layers formed on the bottom surface of the through via hole.

16. The method according to claim 15, wherein
the first gate insulating layer is a SiN layer, and
the second gate insulating layer is a SiO layer.

17. The method according to claim 14, wherein
forming the second portion includes:
processing the first insulating layer in a pattern of the second portion and exposing the first electrode, and
filling the pattern with a second composite oxide semiconductor containing a plurality of metals that are same as the first composite oxide semiconductor.

18. The method according to claim 17, wherein
forming the second portion includes additionally forming the first insulating layer to cover the second composite oxide semiconductor.

19. The method according to claim 17, wherein
both the first and second composite oxide semiconductors contain a first metal, an oxygen binding strength of which is lower than the other metals, and
a concentration of the first metal in the second composite oxide semiconductor is higher than a concentration of the first metal in the first composite oxide semiconductor.

20. The method according to claim 17, wherein
both the first and second composite oxide semiconductors contains a second metal, an oxygen binding strength of which is higher than the other metals, and
a concentration of the second metal in the first composite oxide semiconductor is higher than a concentration of the second metal in the second composite oxide semiconductor.
